(19) United States
(12) Patent Application Publication
(10) Pub. No.: US 2017/0183431 A1
(43) Pub. Date: Jun. 29, 2017

(54) SOLAR CELL ENCAPSULATION SHEET

(71) Applicant: SUMITOMO CHEMICAL COMPANY, LIMITED, Tokyo (JP)

(72) Inventor: Hiroaki YODA, Ichihara-shi (JP)

(21) Appl. No.: 15/386,435

(22) Filed: Dec. 21, 2016

(30) Foreign Application Priority Data
Dec. 24, 2015 (JP) 2015-251057

(51) Int. Cl. C08F 210/08; H01L 31/0203; C08F 210/02; C08F 210/16; C08J 5/18; C08K 3/36

(52) U.S. Cl. CPC C08F 210/08; C08J 5/18; C08K 3/36; C08F 210/02; C08F 210/16; H01L 31/0203; C08F 2500/12; C08F 2500/18; C08J 2323/20

(57) ABSTRACT

The present invention relates to a solar cell encapsulant sheet enables achievement of a higher conversion efficiency of a solar cell and can suppress a PID phenomenon of a solar cell well, and specifically, it provides a solar cell encapsulant sheet formed of a material comprising at least one ethylene resin selected from the group consisting of an ethylene-α-olefin copolymer, an ethylene homopolymer, and an ethylene-unsaturated ester copolymer, wherein the volume resistivity value of the material measured at 23° C. is 1×10¹⁷ Ω·cm or cm more and the average luminous transmittance of the material within a wavelength range of from 400 nm to 1200 nm is 91% or more.

### TECHNICAL FIELD

The present invention relates to solar cell encapsulation sheets.

### BACKGROUND ART

In recent years, solar cells are becoming more prevalent as power generation devices suitable for use of renewable energy.

Generally, a solar cell is composed of a light-receiving surface protector made of glass, a solar cell element (i.e., power generation element), an encapsulant sheet, and a backsheet, and a sheet made of an ethylene-vinyl acetate copolymer, an ethylene-α-olefin copolymer, or the like has been used as the encapsulant sheet (see, for example, Patent Documents 1 and 2).

### RELATED ART DOCUMENTS

[Patent Document 1] JP-A-2014-27034

[Patent Document 2] WO 2014/189019 A

### SUMMARY OF THE INVENTION

### Problems to be Solved by the Invention

Solar cells may be used under high voltages.

However, it is known that use of a solar cell under a high voltage tends to result in a PID (Potential Induced Degradation) phenomenon in which the output of a solar cell drops if the solar cell is used under a high voltage, and members to constitute a solar cell, such as an encapsulant sheet, is required to be able to suppress the PID phenomenon. An encapsulant sheet disposed on the side of a light-receiving surface tends to influence the conversion efficiency of a solar cell. Accordingly, there is a demand for solar cell encapsulant sheet capable of enhancing the conversion efficiency of solar cells and also capable of well suppressing the PID phenomenon.

Moreover, solar cells containing N type silicon as power generation element have recently attracted much attention because of its higher power generation efficiency than that of conventional solar cells. Solar cells containing N type silicon as power generation elements, however, are more difficult to suppress the PID phenomenon than conventional solar cells. Accordingly, there is a demand for solar cells encapsulant sheet capable of enhancing the conversion efficiency of solar cells and also capable of well suppressing the PID phenomenon also in solar cells containing N type silicon as a power generation element.

An object of the present invention is to provide a solar cell encapsulant sheet that enables achievement of a higher conversion efficiency of a solar cell and can suppress a PID phenomenon of a solar cell well.

### Means for Solving the Problems

The present invention relates to a solar cell encapsulant sheet formed of a material comprising at least one ethylene resin selected from the group consisting of an ethylene-α-olefin copolymer, an ethylene homopolymer, and an ethylene-unsaturated ester copolymer, wherein the volume resistivity of the material measured at 23° C. is 1×10¹⁷ Ω·cm or more and the average luminous transmittance of the material within a wavelength of from 400 nm to 1200 nm is 91% or more. In the following, a “solar cell encapsulant sheet” may be referred simply as an “encapsulant sheet.” An item expressed briefly by “encapsulant sheet” means a “solar cell encapsulant sheet.” The material that forms an encapsulant sheet may hereinafter be called a “sheet-forming material.” That is, an encapsulant sheet is formed of a sheet-forming material.

### Advantageous Effects of the Invention

According to the present invention, there can be provided an encapsulant sheet that enables achievement of a higher conversion efficiency of a solar cell and can suppress a PID phenomenon of a solar cell well.

### MODE FOR CARRYING OUT THE INVENTION

### [Ethylene Resin]

The ethylene resin contained in the material that forms the encapsulant sheet of the present invention is at least one ethylene resin selected from the group consisting of an ethylene-α-olefin copolymer, an ethylene homopolymer, and an ethylene-unsaturated ester copolymer.

From the viewpoint of achieving a higher conversion efficiency of a solar cell and the viewpoint of more effectively preventing fracture of a solar cell element during the encapsulation, the Vicat softening point of the ethylene resin to be used in the present invention is preferably 90° C. or less, more preferably 85° C. or less. The Vicat softening point is measured in accordance with JIS K7206-1979.

### [Ethylene-α-Olefin Copolymer]

The ethylene-α-olefin copolymer to be used as the ethylene resin is a copolymer comprising monomer units derived from ethylene and monomer units derived from an α-olefin having 3 to 20 carbon atoms. Examples of the α-olefin include propylene, 1-butene, 1-pentene, 1-hexene, 1-heptene, 1-octene, 1-nonene, 1-decene, 1-dodecene, 4-methyl-1-pentene, and 4-methyl-1-hexene, and these α-olefins may be used either individually or in combination. Preferred as the α-olefin is 1-butene, 1-hexene, 4-methyl-1-pentene, or 1-octene.

From the viewpoint of achieving a higher conversion efficiency of a solar cell and the viewpoint of more effectively preventing fracture of a solar cell element during the encapsulation, the content of the monomer units derived from ethylene in the ethylene-α-olefin copolymer is preferably 50% by mass to 99.5% by mass and the content of the monomer units derived from the α-olefin is preferably 0.5% by mass to 50% by mass. Where the total amount of the monomer units derived from ethylene and the monomer units derived from the α-olefin is taken as 100% by mass. When the ethylene-α-olefin copolymer has monomer units derived from two or more α-olefins, the aforementioned content of the monomer units derived from the α-olefin is the total amount of the monomer units derived from the respective α-olefins in the ethylene-α-olefin copolymer. The content of the monomer units derived from ethylene and the content of the monomer units derived from the α-olefin can be measured by infrared spectrometry (an IR method).

Examples of the ethylene-α-olefin copolymer include an ethylene-1-butene copolymer, an ethylene-1-hexene copolymer, an ethylene-4-methyl-1-pentene copolymer, an ethylene-1-octene copolymer, an ethylene-1-butene-1-hexene copolymer, an ethylene-1-butene-4-methyl-1-pentene copolymer, an ethylene-1-butene-1-octene copolymer, and an ethylene-1-hexene-1-octene copolymer; an ethylene-1-butene copolymer, an ethylene-1-hexene copolymer, an ethylene-4-methyl-1-pentene copolymer, an ethylene-1-butene-1-hexene copolymer, an ethylene-1-butene-1-octene copolymer, or an ethylene-1-hexene-1-octene copolymer is preferred. These ethylene-α-olefin copolymers may be used either individually or in combination.

From the viewpoint of achieving a higher conversion efficiency of a solar cell and the viewpoint of achieving better peelability of a sheet-forming material from a roll during the production of an encapsulant sheet, the upper limit of the density of the ethylene-α-olefin copolymer is preferably 950 kg/m³, more preferably 920 kg/m³, even more preferably 910 kg/m³, and even more preferably 905 kg/m³. From the viewpoint of more effectively suppressing the PID phenomenon and the viewpoint of more effectively preventing undesirable adhesion between encapsulant sheets, the lower limit of the density is preferably 860 kg/m³, more preferably 880 kg/m³, and even more preferably 900 kg/m³. The density is measured in accordance with Method A disclosed in JIS K7112-1980. The density of the ethylene-α-olefin copolymer can be adjusted by adjusting the content of the monomer units derived from ethylene in the ethylene-α-olefin copolymer.

From the viewpoint of reducing extrusion load applied during the production of an encapsulant sheet, the lower limit of the melt flow rate (hereinafter may be indicated as “MFR”) of the ethylene-α-olefin copolymer is preferably 0.01 g/10 minutes, and more preferably 0.1 g/10 minutes. From the viewpoint of achieving higher mechanical strength of an encapsulant sheet, the upper limit of the MFR is preferably 100 g/10 minutes, more preferably 50 g/10 minutes, and even more preferably 30 g/10 minutes. The MFR is a value measured at a temperature of 190° C. and a load of 21.18 N in accordance with Method A provided for in JIS K7210-1995. The MFR of the ethylene-α-olefin copolymer can be adjusted by, for example, adjusting the hydrogen concentration or the polymerization temperature during the production of the ethylene-α-olefin copolymer by polymerization; a higher hydrogen concentration or polymerization temperature affords a larger MFR of the resulting ethylene-α-olefin copolymer.

Examples of the ethylene-α-olefin copolymer include an ethylene-α-olefin copolymer having a ratio of heat of fusion in a temperature range of 20° C. to 110° C. to the total heat of fusion measured by differential scanning calorimetry (this ratio may hereinafter be denoted by “HL110”) of 85%0/or more, and an ethylene-α-olefin copolymer having an HL110 of less than 85%. Hereinafter, the ethylene-α-olefin copolymer having an HL110 of 85% or more may be called “ethylene-α-olefin copolymer (X)” and the ethylene-α-olefin copolymer having an HL110 of less than 85% may be called “ethylene-α-olefin copolymer (Y).”

From the viewpoint of achieving a higher conversion efficiency of a solar cell, the HL110 of the ethylene-α-olefin copolymer (X) is preferably 90% or more, more preferably 95% or more. The HL110 of the ethylene-α-olefin copolymer (X) can be adjusted by adjusting the density or the copolymer or the composition distribution of the copolymer. The “composition distribution of a copolymer” is the intermolecular distribution of comonomer content.

The HL110 is determined by the following method. HL110 is measured using a differential scanning calorimeter (for example, Diamond® DSC manufactured by PerkinElmer). A sample (4 to 10 mg in weight) is put into an aluminum pan, held at 150° C. for 5 minutes, then cooled from 150° C. to 20° C. at a temperature ramp-down rate of 5° C./minute, held at 20° C. for 2 minutes, then heated from 20° C. to 150° C. at a temperature ramp-up rate of 5° C./minute, and the amount of heat absorbed is measured during the heating, and a melting curve is produced. On the melting curve, the point corresponding to the temperature at which the curve flattens and the point corresponding to a temperature of 20° C. are connected by a straight line, which is defined as a baseline. Then, the total area of the region surrounded by the baseline and the melting curve (the total area corresponds to the total heat of fusion) and the area of the region from 20° C. to 110° C. (this area corresponds to the heat of fusion in the range of 20° C. to 110° C.) are determined, and then HL110 is calculated from the following formula:

HL110(%)=(the heat of fusion in the range of 20° C. to 110° C.)/(the total heat of fusion)×100

From the viewpoint of reducing extrusion load applied during the production of an encapsulant sheet, the ethylene-α-olefin copolymer (X) preferably has long chain branches. In the present invention, a “long chain branch” is a branch having five or more carbon atoms. The long chain branch is preferably an alkyl group having five or more carbon atoms.

From the viewpoint of reducing extrusion load applied during the production of an encapsulant sheet, the number of long chain branches (hereinafter may be referred to as “NLCB”) of the ethylene-α-olefin copolymer (X) is preferably 0.05 or more, and more preferably 0.08 or more. From the viewpoint of achieving higher mechanical strength of an encapsulant sheet, the NLCB is preferably 1.0 or less, more preferably 0.70 or less, and even more preferably 0.50 or less.

The NLCB of the ethylene-α-olefin copolymer (X) can be adjusted by changing the type of a catalyst that is high in macromer-generating ability and high in copolymerizing ability, and the combination of the catalyst and a co-catalyst.

NLCB is obtained by determining the ratio of the area of peaks derived from methine carbon to which a branch having 5 or more carbon atoms is attached, from a 13C-NMR spectrum measured by a carbon nuclear magnetic resonance (13C-NMR) method, while taking the sum of the areas of all peaks observed within a chemical shift range of 5 to 50 ppm as 1000. The peak derived from methine carbon to which a branch having 5 or more carbon atoms is attached is observed in the vicinity of 38.2 ppm. (Reference: scientific articles “Macromolecules”, (U.S.A.), The American Chemical Society, 1999, vol. 32, pp. 3817-3819) Since a position of this peak derived from methine carbon to which a branch having 5 or more carbon atoms is attached, is shifted depending on a measurement apparatus and measurement condition in some cases, usually, the position is determined by performing measurement of an authentic sample for every measurement apparatus and measurement condition. For spectral analysis, it is preferred to use a negative exponential function as a window function.

From the viewpoint of achieving a higher conversion efficiency of a solar cell and the viewpoint of reducing extrusion load applied during the production of an encapsulant sheet, the activation energy of flow (hereinafter may be expressed by “Ea”) of the ethylene-α-olefin copolymer (X) is 30 kJ/mol or more, preferably 40 kJ/mol or more, and even more preferably 50 kJ/mol or more. From the viewpoint of achieving higher mechanical strength of an encapsulant sheet, Ea is 100 kJ/mol or less, preferably 90 kJ/mol or less, and even more preferably 80 kJ/mol or less.

The Ea of the ethylene-α-olefin copolymer (X) can be adjusted by changing the type of a catalyst that is high in macromer-generating ability and high in copolymerizing ability, and the combination of the catalyst and a co-catalyst.

Ea is a numerical value calculated using an Arrhenius type equation from the shift factor in the preparation of a master curve showing the dependency of melting complex viscosity (unit: Pa·sec) on angular frequency (unit: rad/sec) at 190° C. on the basis of the temperature-time superposition principle, and is a value obtained by the method as described below. A shift factor (aT) at each temperature (T) of 130° C., 150° C., 170° C., and 190° C. is determined by superposing melting complex viscosity (unit: Pa·sec)-angular frequency (unit: rad/sec) curves of an olefin polymer at the respective temperatures (T, unit: ° C.) on melting complex viscosity-angular frequency curve of the olefin polymer at 190° C. on the basis of the temperature-time superposition principle about every melting complex viscosity-angular frequency curve at each temperature (T). Then, a linear approximate equation (the following formula (II)) of [ln(aT)] and [1/(T+273.16)] is calculated by the least squares method from the temperatures (T) and the shift factors (aT) at the respective temperatures (T). Subsequently, Ea is determined from the gradient m of the primary expression and the following formula (III):

ln(aT)=m(1/(T+273.16))+n (II)

Ea=|0.008314×m| (III)

aT: shift factor

Ea: activation energy of flow (unit: kJ/mol)

T: temperature (unit: ° C.)

The calculation may use commercially available calculation software, and examples of the calculation software include Rhios V.4.4.4 produced by Rheometrics.

In this connection, the shift factor (aT) is shift amount when both logarithmic curves of melting complex viscosity-angular frequency at the respective temperatures (T) are shifted to the direction of log (Y)=−log(X) axis, provided that Y-axis indicates melting complex viscosity and X-axis indicates angular frequency, and are superposed on melting complex viscosity-angular frequency curve at 190° C. In the superposition, both logarithmic curves of melting complex viscosity-angular frequency at the respective temperatures (T) are shifted to aT times in angular frequency and to 1/aT times in melting complex viscosity, with regard to curve. In addition, the correlation coefficient in calculating the formula (II) by the least-square method from the values at four points of 130° C., 150° C., 170° C., and 190° C., is generally not less than 0.99.

The method for producing the ethylene-α-olefin copolymer (X) may be, for example, a method in which ethylene and an α-olefin having 3 to 20 carbon atoms are copolymerized in the presence of a catalyst prepared by bringing a co-catalyst carrier (A), a zirconium complex (B) having a plurality of cyclopentadiene type anion structures and an organoaluminum compound (C) into contact with each other. Examples of the co-catalyst carrier (A) include a carrier obtainable by bringing (a) diethylzinc, (b) fluorinated phenol, (c) water, (d) silica, and (e) a trimethylsilylating agent into contact with each other.

Examples of the complex (B) include a zirconium complex having an optionally substituted cyclopentadienyl group, a zirconium complex having an optionally substituted indenyl group, and a zirconium complex having an optionally substituted fluorenyl group, specifically include a crosslinked bis(optionally substituted cyclopentadienyl)zirconium complex in which optionally substituted cyclopentadienyl group are bridged with a bridging group, and more specifically include racemic ethylenebis (1-indenyl)zirconium dichloride and racemic ethylenebis(1-indenyl)zirconium diphenoxide.

Examples of the trimethylsilylating agent (e) include hexamethyldisilazane ((CH₃)₃Si)₂NH), chlorotrimethylsilane, and N,O-bis(trimethylsilyl)acetamide.

While the use amounts of the components (a). (b), and (c) are not particularly limited, it is preferred that y and z satisfy the following formula where the molar ratio of the use amounts of the respective components are component (a):component (b):component (c)=1:y:z.

|2−y−2z≦1

y in the above formula is preferably 0.01 to 1.99, more preferably 0.10 to 1.80, even more preferably 0.20 to 1.50, and even more preferably 0.30 to 1.00.

Examples of the method for producing the ethylene-α-olefin copolymer (Y) include a slurry polymerization method, a solution polymerization method, a bulk polymerization method, a gas phase polymerization method, etc. using a Ziegler-Natta catalyst or a complex-based catalyst such as a metallocene complex and a non-metallocene complex. The HL110 of the ethylene-α-olefin copolymer (Y) can be adjusted by adjusting the density or the copolymer or the composition distribution of the copolymer.

### [Ethylene Homopolymer]

Preferred as the ethylene homopolymer to be used as the ethylene resin is an ethylene homopolymer produced by polymerizing ethylene by a high-pressure process. One specific example is an ethylene homopolymer produced by polymerizing ethylene in the presence of a radical generator at a polymerization pressure of 140 MPa to 300 MPa and a polymerization temperature of 200° C. to 300° C. by using a vessel type reactor or a tube type reactor.

From the viewpoint of achieving a higher conversion efficiency of a solar cell, the lower limit of the density of the ethylene homopolymer is preferably 920 kg/m³, more preferably 925 kg/m³, and even more preferably 928 kg/m³, and from the viewpoint of achieving a higher conversion efficiency of a solar cell, the upper limit of the density is preferably 935 kg/m³, and more preferably 938 kg/m³. The density is measured in accordance with Method A provided for in JIS K7112-1980 after performing the annealing disclosed in JIS K6760-1995.

### [Ethylene-Unsaturated Ester Copolymer]

The ethylene-unsaturated ester copolymer to be used as the ethylene resin is a copolymer comprising monomer units derived from ethylene and monomer units derived from an unsaturated ester.

The unsaturated ester is a compound having a vinyl group and an ester linkage in the molecule thereof, and examples of the unsaturated ester include vinyl esters of carboxylic acids, alkyl esters of unsaturated carboxylic acids, and glycidyl esters of unsaturated carboxylic acids. The unsaturated ester is preferably selected from the group consisting of vinyl esters of carboxylic acids and alkyl esters of unsaturated carboxylic acids. Examples of the vinyl esters of carboxylic acids include vinyl acetate and vinyl propionate. Examples of the alkyl esters of unsaturated carboxylic acids include methyl acrylate, ethyl acrylate, butyl acrylate, methyl methacrylate, and ethyl methacrylate. Examples of the glycidyl esters of unsaturated carboxylic acids include glycidyl acrylate and glycidyl methacrylate. Such unsaturated esters may be used either individually or in combination.

Examples of the ethylene-unsaturated ester copolymer include an ethylene-vinyl acetate copolymer, an ethylene-vinyl propionate copolymer, an ethylene-methyl acrylate copolymer, an ethylene-ethyl acrylate copolymer, an ethylene-butyl acrylate copolymer, an ethylene-methyl methacrylate copolymer, an ethylene-ethyl methacrylate copolymer, an ethylene-glycidyl methacrylate copolymer, and an ethylene-vinyl acetate-methyl methacrylate copolymer. Such ethylene-unsaturated ester copolymers may be used either individually or in combination.

From the viewpoint of achieving a higher conversion efficiency of a solar cell and the viewpoint of achieving better peelability of a sheet-forming material from a roll during the production of an encapsulant sheet and the viewpoint of achieving a higher conversion efficiency of a solar cell, the content of the monomer units derived from ethylene in the ethylene-unsaturated ester copolymer is preferably 65% by mass to 80% by mass, more preferably 67% by mass to 77% by mass, and even more preferably 68% by mass to 75% by mass.

From the viewpoint of achieving better peelability of a sheet-forming material from a roll during the production of an encapsulant sheet and the viewpoint of achieving better peelability and the viewpoint of achieving a higher conversion efficiency of a solar cell, the content of the monomer units derived from the unsaturated ester in the ethylene-unsaturated ester copolymer is preferably 20% by mass to 35% by mass, more preferably 23% by mass to 33% by mass, and even more preferably 25% by mass to 32% by mass. It is noted that the total amount of the monomer units derived from ethylene and the monomer units derived from the unsaturated ester is taken as 100% by mass.

When the ethylene-unsaturated ester copolymer contains monomer units derived from two or more unsaturated esters, the content of the monomer units derived from the unsaturated ester is the total amount of the monomer units derived from the respective unsaturated esters contained in the ethylene-unsaturated ester copolymer.

The content of the monomer units derived from ethylene and the content of the monomer units derived from the unsaturated ester can be measured by infrared spectrometry (an IR method).

From the viewpoint of achieving better peelability of a sheet-forming material from a roll during the production of an encapsulant sheet, the upper limit of the melt flow rate (MFR) of the ethylene-unsaturated ester copolymer is preferably 50 g/10 minutes, more preferably 40 g/10 minutes. From the viewpoint of reducing extrusion load applied during the production of an encapsulant sheet, the lower limit of the MFR is preferably 4 g/10 minutes, more preferably 5 g/10 minutes. MFR is measured at a temperature of 190° C. and a load of 21.18 N by the method specified in JIS K7210-1995. The MFR of the ethylene-unsaturated ester copolymer can be adjusted by, for example, adjusting the hydrogen concentration and the polymerization temperature applied in the production of the ethylene-unsaturated ester copolymer by polymerization.

From the viewpoint of reducing extrusion load applied during the production of an encapsulant sheet, the lower limit of the molecular weight distribution (Mw/Mn) of the ethylene-unsaturated ester copolymer is preferably 2, more preferably 2.5, and even more preferably 3. From the viewpoint of achieving higher mechanical strength of an encapsulant sheet, the upper limit of the molecular weight distribution (Mw/Mn) is preferably 8, more preferably 5, even more preferably 4.5, and still more preferably 4. Molecular weight distribution is determined using a gel permeation chromatograph. It is noted that Mw denotes a polystyrene-equivalent weight average molecular weight and Mn denotes a polystyrene-equivalent number average molecular weight.

From the viewpoint of achieving better peelability of a sheet-forming material from a roll during the production of an encapsulant sheet, the polyethylene-equivalent weight average molecular weight of the ethylene-unsaturated ester copolymer is preferably 40000 to 80000, more preferably 50000 to 70000. The polyethylene-equivalent weight average molecular weight is a product of the polystyrene-equivalent weight average molecular weight determined through gel permeation chromatographic measurement and a ratio of Q factors of polyethylene and polystyrene (17.7/41.3).

The method for producing the ethylene-unsaturated ester copolymer may be a method involving copolymerizing ethylene with an unsaturated ester in the presence of a radical generator known in the art.

[(A) At least one compound selected from the group consisting of silicon dioxide, zeolite, a bismuth oxide based compound, an antimony oxide based compound, a titanium phosphate based compound, and a zirconium phosphate based compound]

The sheet-forming material may comprise at least one compound selected from the group consisting of silicon dioxide, zeolite, a bismuth oxide based compound, an antimony oxide based compound, a titanium phosphate based compound, and zirconium phosphate based compound (the at least one compound may hereinafter be referred to as compound (A)). The sheet-forming material may contain either a single compound or two or more compounds as the compound (A). For example, it may contains silicon dioxide and zeolite and may contain non-calcined amorphous silicon dioxide and calcined amorphous silicon dioxide.

The silicon dioxide is a compound represented by a formula SiO₂, and examples thereof include crystalline silicon dioxide and amorphous silicon dioxide. Examples of the amorphous silicon dioxide include calcined amorphous silicon dioxide and non-calcined amorphous silicon dioxide.

Examples of the crystalline silicon dioxide include CRYSTALITE produced by Tatsumori Ltd. Examples of the calcined amorphous silicon dioxide include a calcined silica CARPLEX CS-5 produced by Evonik Degussa Japan Co., Ltd. Examples of the non-calcined amorphous silicon dioxide include VK-SP 30S produced by Xuan Cheng Jing Rui New Material Co., Ltd., China, porous silica produced by Suzuki Yushi Industrial Co., Ltd., Gasil AB905 produced by PQ Corporation, Snow Mark SP-5 produced by MARUKAMA Co., Ltd., silica CARPLEX #80, CARPLEX EPS-2, and CARPLEX FPS-101 produced by Evonik Degussa Japan Co., Ltd.

From the viewpoint of achieving a higher conversion efficiency of a solar cell and the viewpoint of more effectively suppressing the PID phenomenon, the silicon dioxide is preferably amorphous silicon dioxide, more preferably non-calcined amorphous silicon dioxide.

From the viewpoint of more effectively suppressing the PID phenomenon, the ignition loss of silicon dioxide is preferably 1.3% or more, more preferably 1.5% or more, even more preferably 2% or more, and still more preferably 3% or more. From the viewpoint of more effectively suppressing the PID phenomenon, the ignition loss of silicon dioxide is preferably 15% or less, preferably 13% or less, and even more preferably 10% or less. The ignition loss is a value measured in accordance with the method defined in JIS K1150-1994 using a sample dried at about 150° C. under vacuum.

Said zeolite is a material that is represented by the formula M_{2/n}O.Al₂O₃.xSiO₂.yH₂O (M represents Na, K, Ca or Ba, n represents the valence number of atom M; x represents a number of 2 to 10, and y represents a number of 2 to 7) and that has a structure in which alkali metal, alkaline earth metal, or water molecules are contained in pores formed within a three-dimensional network structure formed by AlO₄ tetrahedrons or SiO₄ tetrahedrons sharing their vertexes together. In the present invention, either natural zeolite or synthetic zeolite may be used. Examples of the natural zeolite include analcite, chabazite, erionite, natrolite, mordenite, clinoptilolite, heulandite, stilbite, and laumontite. Examples of the synthetic zeolite include A type zeolite, X type zeolite, Y type zeolite, L type zeolite, and ZSM-5. The synthetic zeolite can be obtained by well mixing starting materials, such as sodium silicate, sodium aluminate, and silica gel to deposit crystals from the starting material mixture at a temperature of 80° C. to 120° C., and washing the crystals with water to a pH of 9 to 12, followed by filtration.

Examples of such zeolite include High Silica Zeolite HSZ-series 820NHA, 822HOA, 643NHA, and 842HOA produced by TOSOH Corporation, and Molecular Sieve-series 3A and 4A produced by UNION SHOWA K.K.

From the viewpoint of more effectively suppressing the PID phenomenon, the ignition loss of the zeolite is preferably 1.3% or more, more preferably 1.5% or more, even more preferably 2% or more, still more preferably 3% or more, and further preferably 4% or more. The ignition loss of the zeolite is preferably 15% or less, more preferably 13% or less, and even more preferably 10% or less. The ignition loss is a value measured in accordance with the method defined in JIS K1150-1994 using a sample dried at about 150° C. under vacuum.

The bismuth oxide based compound, the antimony oxide based compound, the titanium phosphate based compound, and the zirconium phosphate based compound are inorganic compounds with ion-capturing ability.

Examples of the bismuth oxide based compound include IXE-500 produced by Toagosei Co., Ltd.

Examples of the antimony oxide based compound include IXE-300 produced by Toagosei Co., Ltd.

Examples of the phosphoric acid titanium based compound include IXE-400 produced by Toagosei Co., Ltd.

Examples of the zirconium phosphate based compound include IXE-100.

From the viewpoint of the easy uniform dispersibility in an encapsulant sheet, the average particle size of the compound (A) is preferably 0.001 μm to 30 μm, more preferably 0.01 μm to 10 μm.

The average particle size of the compound (A) is defined and measured as described below. A dispersion liquid in which that compound is dispersed in ethanol is irradiated with laser beams, which are thereby scattered, and the scattering light is collected with a lens. At this time, from a diffraction pattern formed on a focal plane, particle size distribution is measured on a volume basis. The median particle diameter of the resulting particle size distribution is an average particle size.

Examples of the method for adjusting the average particle diameter of the compound (A) to 0.001 μm to 30 μm include a method of crushing the compound (A) with a mortar and a method of pulverizing the compound with a jet mill.

When at least one selected from the group consisting of the ethylene-α-olefin copolymer (Y), the ethylene homopolymer, and the ethylene-unsaturated ester copolymer is used as the ethylene resin, it is preferred from the viewpoint of achieving a higher conversion efficiency of a solar cell and the viewpoint of more effectively suppressing the PID phenomenon that the sheet-forming material preferably contains the above-mentioned compound (A). From the viewpoint of achieving a higher conversion efficiency of a solar cell and the viewpoint of more effectively suppressing the PID phenomenon, the compound (A) is preferably silicon dioxide or zeolite.

When the sheet-forming material contains the compound (A), it is preferred from the viewpoint of more effectively suppressing the PID phenomenon that the lower limit of the content of the compound (A) is 0.001 parts by mass, more preferably 0.01 parts by mass, even more preferably 0.1 parts by mass, and the upper limit of the content of the compound (A) is preferably 5 parts by mass, more preferably 0.5 parts by mass. It is noted that the amount of the ethylene resin is taken as 100 parts by mass.

The sheet-forming material may contain a crosslinking agent. Examples of the crosslinking agent include compounds capable of generating a radical at a temperature exceeding the melting point of the ethylene resin to be used in the present invention, and preferred is an organic peroxide whose one-hour half-life temperature is higher than the melting point of the ethylene resin contained in the sheet-forming material. An organic peroxide whose one-hour half-life temperature is 70° C. to 150° C. is more preferred as the crosslinking agent because it hardly is decomposed during its processing into an encapsulant sheet but it is decomposed on heating at the time of fabrication of a solar cell and facilitates crosslinking of the ethylene resin. Moreover, an organic peroxide having a one-hour half-life temperature of not lower than 100° C. is more preferable because it hardly is decomposed during its processing into an encapsulant sheet; examples thereof include tert-butylperoxy-2-ethylhexyl carbonate, 2,5-dimethylhexane-2,5-dihydroperoxide, and dialkyl peroxides. These may be used either individually or in combination.

Dialkyl peroxides are compounds having no polar groups other than a peroxy group and having two alkyl groups attached to the peroxy groups. Examples of the polar group include —COO—, —CO—, —OH, and —NH₂. It is noted that a plurality of peroxy groups may be contained in a single molecule. Examples of the dialkyl peroxide include di(2-tert-butylperoxyisopropyl)benzene, dicumyl peroxide, 2,5-dimethyl-2,5-di(tert-butylperoxy)hexane, tert-butylcumyl peroxide, di-tert-butyl peroxide, and 2,5-dimethyl-2,5-di(tert-butylperoxy)hexyne-3. These may be used either individually or in combination. A dialkyl peroxide and a crosslinking agent other than dialkyl peroxides may be used together.

When the sheet-forming material contains the crosslinking agent, a crosslinking agent remaining undecomposed after being heated during fabrication of a solar cell may be decomposed slowly during use of the solar cell to cause degradation, such as discoloration, of the encapsulant sheet. From the viewpoint of more effective suppression of degradation of an encapsulant sheet by such a remaining crosslinking agent, the content of the crosslinking agent is preferably 0.001 parts by mass to 5 parts by mass relative to 100 parts by mass of the ethylene resin, and from the viewpoint of suppression of bubble generation at the time of fabrication of a solar cell, the content of the crosslinking agent is preferably 0.001 parts by mass to 2 parts by mass.

The sheet-forming material may contain a crosslinking aid. Examples of the crosslinking aid include a monofunctional crosslinking aid, a bifunctional crosslinking aid, a trifunctional crosslinking aid, and a crosslinking aid having four or more (meth)acryloyl groups. Examples of the monofunctional crosslinking aid include methyl acrylate and methyl methacrylate. Examples of the bifunctional crosslinking aid include N,N′-m-phenylenebismaleimide. Examples of the trifunctional crosslinking aid include triallyl isocyanurate and trimethylolpropane triacrylate. These may be used either individually or in combination.

The crosslinking aid having four or more (meth)acryloyl groups is a compound having four or more (meth)acryloyl groups in a single molecule. Specific examples include pentaerythritol tetra(meth)acrylate, ditrimethylolpropane tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, and a dimer of pentaerythritol tri(meth)acrylate. These may be either acrylic acid adducts or acrylic ester adducts, and these may have been modified with ethylene oxide or propylene oxide. Specific examples include a pentaerythritol tetra(meth)acrylate monoacrylic acid adduct, ethylene oxide-modified pentaerythritol tetra(meth)acrylate, and ethylene oxide-modified dipentaerythritol penta(meth)acrylate. These may be used either individually or in combination. A crosslinking aid having four or more (meth)acryloyl groups and a crosslinking aid other than crosslinking aids having four or more (meth)acryloyl groups may be used in combination. In the present specification, the term “(meth)acryloyl group” refers to a methacryloyl group or an acryloyl group, and the term “(meth)acrylate” refers to a methacrylate or an acrylate.

Examples of the crosslinking aid having four or more (meth)acryloyl groups include urethane poly(meth)acrylate. The urethane poly(meth)acrylate can be synthesized from, for example, an organic isocyanate and a hydroxyl group-containing (meth)acrylate.

Examples of commercially available products of the crosslinking aid having four or more (meth)acryloyl groups include “A-DPH”, “AD-TMP”. “U-4HA”, “U-6HA”, “U-6LPA”, “U-15HA”, “UA-122P”, “UA-33H”, “A-9550”, “ATM-35E”, “A-DPH-6E”, “A-DPH-12E”, “M-DPH-6E”, and “M-DPH-12E” produced by Shin-Nakamura Chemical Co., Ltd., “UA-306H”, “UA-306T”, “UA3061”, and “UA510H” produced by Kyoeisha Chemical Co., Ltd., “KRM8452”, “EB1290”, “EB5129”, “KRM7864”, and “EB1290K” produced by DAICEL-ALLNEX LTD., “Viscoat 802” produced by Osaka Organic Chemical Industry Ltd., and “UV7600B”. “UV7605B”, “UV7610B”, and “UV7620EA” produced by The Nippon Synthetic Chemical Industry Co., Ltd.

These may be used either individually or in combination.

When the sheet-forming material contains the crosslinking aid, the amount of the crosslinking aid is preferably 10 parts by or less, more preferably 0.1 parts by mass to 5 parts by mass, and even more preferably 0.5 parts by mass to 2.0 parts by mass, relative to 100 parts by mass of the ethylene resin.

When using the crosslinking agent and the crosslinking aid in combination, it is preferred from the viewpoint of achieving a higher conversion efficiency of a solar cell and the viewpoint of more effectively suppressing the PID phenomenon that the mass ratio of the content of the crosslinking aid to the content of the crosslinking agent is 0.3 to 2.5, more preferably 0.4 to 1.9, and even more preferably 0.5 to 1.5.

When an ethylene-unsaturated ester copolymer is used as the ethylene resin, it is preferred from the viewpoint of achieving a higher conversion efficiency of a solar cell and the viewpoint of more effectively suppressing the PID phenomenon that the sheet-forming material preferably contains at least one compound selected from the group consisting of the dialkyl peroxide and the crosslinking aid having four or more (meth)acryloyl groups (the at least one compound may hereinafter be referred to as compound (B)).

The sheet-forming material may contain either a single compound or two or more compounds as the compound (B). The sheet-forming material may contain a dialkyl peroxide and a crosslinking aid having four or more (meth)acryloyl groups, and also may contain two or more dialkyl peroxides.

When at least one selected from the group consisting of the ethylene-α-olefin copolymer (Y) and the ethylene homopolymer is used as the ethylene resin, it is preferred from the viewpoint of achieving a higher conversion efficiency of a solar cell that the mass ratio of the content of the crosslinking aid to the content of the dialkyl peroxide is 0.3 to 1.2, more preferably 0.4 to 0.7.

When the ethylene-unsaturated ester copolymer is used as the ethylene resin, it is preferred from the viewpoint of more effectively suppressing the PID phenomenon that the sheet-forming material contains the dialkyl peroxide and the crosslinking aid having four or more (meth)acryloyl groups. From the viewpoint of more effectively suppressing the PID phenomenon, the mass ratio of the content of the crosslinking aid having four or more (meth)acryloyl groups to the content of the dialkyl peroxide is preferably 0.3 to 1.2, more preferably 0.4 to 1.1.

The sheet-forming material may, if necessary, contain a silane coupling agent, a UV absorber, an antioxidant, an antifogging agent, a plasticizer, a surfactant, a coloring agent, an antistatic agent, a discoloration inhibitor, a flame retardant, a crystallization nucleator, a lubricant, a light stabilizer, etc.

Examples of the UV absorber include a benzophenone-based UV absorber, a benzotriazole-based UV absorber, a hindered amine UV absorber, a triazine-based UV absorber, a salicylic acid-based UV absorber, and a cyanoacrylate-based UV absorber. UV absorbers may be used either individually or in combination.

Examples of the benzophenone-based UV absorber include 2-hydroxy-4-octoxybenzophenone and 2-hydroxy-4-methoxy 5-sulfobenzophenone.

Examples of the benzotriazole-based UV absorber include
2-(2′-hydroxy-5-methylphenyl)benzotriazole,
2-(2H-1,2,3-benzotriazol-2-yl)-4,6-di-tert-butylphenol;
2-(5-chloro-2H-1,2,3-benzotriazol-2-yl)-4,6-di-tert-butylphenol;
2-(2H-1,2,3-benzotriazol-2-yl)-4,6-di-tert-pentyl phenol;
2-(5-chloro-2H-1,2,3-benzotriazol-2-yl)-4,6-di-tert-pentylphenol;
2-(2H-1,2,3-benzotriazol-2-yl)-4-tert-butylphenol;
2-(5-chloro-2H-1,2,3-benzotriazol-2-yl)-4-tert-butylphenol;
2-(2H-1,2,3-benzotriazol-2-yl)-4-methylphenol;
2-(5-chloro-2H-1,2,3-benzotriazol-2-yl)-4-methylphenol;
2-(2H-1,2,3-benzotriazol-2-yl)-6-dodecyl-4-methylphenol;
2-(5-chloro-2H-1,2,3-benzotriazol-2-yl)-6-dodecyl-4-methylphenol;
2-(2H-1,2,3-benzotriazol-2-yl)-4-methyl-6-tert-butylphenol; and
2-(5-chloro-2H-1,2,3-benzotriazol-2-yl)-4-methyl-6-tert-butylphenol.

When the benzophenone-based UV absorber and the benzotriazole-based UV absorber are used in combination as the UV absorber, the sum total of the contents of the benzophenone-based UV absorber and the benzotriazole-based UV absorber is preferably 0.01 parts by mass or more, more preferably 0.1 parts by mass or more, and is preferably 5 parts by mass or less, more preferably 1.0 parts by mass or less, relative to 100 parts by mass of the ethylene resin.

Examples of the hindered amine UV absorber include phenyl salicylate and p-tert-buthylphenyl salicylate. The content of the hindered amine UV absorber is preferably 0.01 parts by mass to 5 parts by mass relative to 100 parts by mass of the ethylene resin.

Examples of the triazine-based UV absorber include
2-(2-hydroxy-4-hydroxymethyl phenyl)-4,6-diphenyl-s-triazine,
2-(2-hydroxy-4-hydroxymethylphenyl)-4,6-bis(2,4-dimethylphenyl)-s-triazine
2-[2-hydroxy-4-(2-hydroxyethyl)phenyl]-4,6-diphenyl-s-triazine,
2-[2-hydroxy-4-(2-hydroxyethyl)pbenyl]-4,6-bis(2,4-dimethylphenyl)-s-triazine,
2-[2-hydroxy-4-(2-hydroxyethoxy)phenyl]-4,6-diphenyl-s-triazine,
2-[2-hydroxy-4-(2-hydroxyethoxy)phenyl]-4,6-bis(2,4-dimethylphenyl)-s-triazine,
2-[2-hydroxy-4-(3-hydroxypropyl)phenyl]-4,6-diphenyl-s-triazine.
2-[2-hydroxy-4-(3-hydroxypropyl)phenyl]-4,6-bis(2,4-dimethylphenyl)-s-triazine,
2-[2-hydroxy-4-(3-hydroxypropoxy)phenyl]-4,6-diphenyl-s-triazine,
2-[2-hydroxy-4-(3-hydroxypropoxy)phenyl]-4,6-bis(2,4-dimethylphenyl)-s-triazine,
2-[2-hydroxy-4-(4-hydroxybutyl)phenyl]-4,6-diphenyl-s-triazine,
2-[2-hydroxy-4-(4-hydroxybutyl)phenyl]-4,6-bis(2,4-dimethylphenyl)-s-triazine,
2-[2-hydroxy-4-(4-hydroxybutoxy)phenyl]-4,6-diphenyl-s-triazine,
2-[2-hydroxy-4-(4-hydroxybutoxy)phenyl]-4,6-bis(2,4-dimethylphenyl)-s-triazine,
2-(2-hydroxy-4-hydroxymethylphenyl)-4,6-bis(2-hydroxy-4-methylphenyl)-s-triazine,
2-[2-hydroxy-4-(2-hydroxyethyl)phenyl]-4,6-bis(2-hydroxy-4-methylphenyl)-s-triazine,
2-[2-hydroxy-4-(2-hydroxyethoxy)phenyl]-4,6-bis(2-hydroxy-4-methylphenyl)-s-triazine,
2-[2-hydroxy-4-(3-hydroxypropyl)phenyl]-4,6-bis(2-hydroxy-4-meth)ylphenyl)-s-triazine.
2-[2-hydroxy-4-(3-hydroxypropoxy)phenyl]-4,6-bis(2-hydroxy-4-methylphenyl)-s-triazine,
2-[4,6-bis(2,4-dimethylphenyl)-1,3,5-triazin-2-yl]-5-(octyloxy)phenol, and
2-(4,6-diphenyl-1,3,5-triazin-2-yl)-5-[(hexyl)oxy]-phenol.

Examples of the salicylic acid-based UV absorber include phenyl salicylate, 4-tert-butylphenyl salicylate, n-hexadecyl 2,5-tert-butyl-4-hydroxybenzoate, and 2,4-di-tert-butylphenyl-3′,5-di-tert-butyl-4′-hydroxybenzoate.

Examples of the cyanoacrylate-based UV absorber include 2-ethylhexyl-2-cyano-3,3′-diphenyl acrylate and ethyl-2-cyano-3,3′-diphenyl acrylate.

Examples of the antioxidant include an amine-based antioxidant, a phenol-based antioxidant, a phosphorus-containing antioxidant, a bisphenyl antioxidant, and a hindered amine antioxidant, and specifically include aryl phosphites, such as di-tert-butyl-p-cresol, bis(2,2,6,6-tetramethyl-4-piperazyl) sebacate, tris(2,4-di-tert-butylphenyl) phosphite, tris(nonylphenyl) phosphite, or triphenyl phosphite; alkyl phosphites, such as trisisodecyl phosphite, trilauryl phosphite, and tris(tridecyl) phosphite: alkylaryl phosphites, such as diphenylisooctyl phosphite, diphenylisodecyl phosphite, diisodecylphenyl phosphite, diisooctyloctylphenyl phosphite, phenylneopentylglycol phosphite, 2,4,6-tri-tert-buthylphenyl(2-butyl-2-ethyl-1,3-propanediol) phosphite, and (2,4,8,10-tetrakis(tert-butyl)-6-{(ethylhexyl)oxy}-12H-dibenzo)[d,g]1,3,2-dioxaphosphocin; octadecyl-3-(3,5-di-tert-butyl-4-hydroxyphenyl)propionate, pentaerythritol-tetrakis[3-(3,5-di-tert-butyl-4-hydroxyphenyl) propionate], 1,3,5-trimethyl-2,4,6-tris(3,5-di-tert-butyl-4-hydroxybenzyl)benzene, thiodiethylene-bis[3-(3,5-di-tert-butyl-4-hydroxyphenyl) propionate], N,N′-hexane-1,6-diylbis[3-(3,5-di-tert-butyl-4-hydroxyphenyl) propionamide], diethyl(3,5-bis(1,1-dimethylethyl)-4-hydroxyphenyl)methyl) phosphate, 3,3′,3″,5,5′,5″-hexa-tert-butyl-α,α′,α″-(mesitylene-2,4,6-triyl)tri-p-cresol, ethylenebis(oxyethylene)bis(3-(5-tert-butyl-4-hydroxy-m-tolyl)propionate), hexamethylene-bis(3-(3,5-di-tert-butyl-4-hydroxyphenyl)propionate), 1,3,5-tris(3,5-di-tert-butyl-4-hydroxybenzyl)-1,3,5-triazine-2,4,6(1H,3H,5H)-trione, 1,3,5-tris((4-tert-butyl-3-hydroxy-2,6-xylyl)methyl)-1,35-triazine-2,4,6(1H,3H,5H)-trione, 2,6-di-tert-butyl 4-(4,6-bis(octylthio)-1,3,5-triazin-2-ylamino)phenol, and 3,9-bis(2-(3-(3-tert-butyl-4-hydroxy-5-methylphenyl)propionyloxy)-1,1-dimethylethyl)-2,4,8,10-tetraoxaspiro(5,5)undecane. The content of the antioxidant is preferably 0.02 parts by mass to 0.5 parts by mass, more preferably 0.05 parts by mass to 0.3 parts by mass, relative to 100 parts by mass of the ethylene resin.

Examples of the coloring agent include white coloring agents such as titanium white and calcium carbonate, blue coloring agents such as ultramarine, black coloring agents such as carbon black, and milk white coloring agents such as glass beads and a light-diffusing agent: titanium white is preferable. The content of such coloring agents is preferably 10 parts by mass or less, more preferably 1 parts by mass to 5 parts by mass, relative to 100 parts by mass of the ethylene resin.

Examples of the plasticizer include esters of polybasic acids and esters of polyhydric alcohols. Specific examples thereof include dioctyl phthalate, dihexyl adipate, triethylene glycol di-2-ethylbutyrate, butyl sebacate, tetraethylene glycol diheptanoate, and triethylene glycol dipelargonate. The content of the plasticizer is preferably 5 parts by mass or less relative to 100 parts by mass of the ethylene resin.

Examples of the discoloration inhibitor include salts of higher fatty acids with metals, such as cadmium and barium. Examples of the salt of a metal with a higher fatty acid include a metallic soap. The content of the discoloration inhibitor is preferably 5 parts by mass or less relative to 100 parts by mass of the ethylene resin.

Examples of the flame retardant include an organic flame retardant contains one or more halogen atoms in its molecule and an inorganic flame retardant containing one or more halogen atoms in its molecule. A chlorine atom or a bromine atom is preferable as the halogen atom.

Examples of the organic flame retardant containing one or more halogen atoms in its single molecule include tris(2,3-dibromopropyl) isocyanurate, chlorinated paraffin, chlorinated polyethylene, hexachloroendomethylenetetrahydrophthalic acid, perchloropentacyclodecane, tetrachlorophthalic anhydride, 1,1,2,2-tetrabromoethane, 1,4-dibromobutane, 1,3-dibromobutane, 1,5-dibromopentane, ethyl α-bromobutyrate, and 1,2,5,6,9,10-hexabromocyclodecane.

Examples of the inorganic flame retardant containing one or more halogen atoms in its single molecule include hydroxides such as aluminum hydroxide and magnesium hydroxide, phosphates such as ammonium phosphate and zinc phosphate, and red phosphorus.

The content of the flame retardant is preferably 70 parts by mass or less, more preferably 1 parts by mass to 50 parts by mass, relative to 100 parts by mass of the ethylene resin.

Antimony trioxide or expanded graphite may further be contained as a flame retardant aid. When expanded graphite is contained as the flame retardant aid, the content of the expanded graphite is preferably 1 part by mass or more, and preferably 25 parts by mass or less, more preferably 17 parts by mass or less, relative to 100 parts by mass of the ethylene resin. When antimony trioxide is contained as the flame retardant aid, the content of the antimony trioxide is preferably 2 parts by mass or more, and preferably 10 parts by mass or less, more preferably 9 parts by mass or less, relative to 100 parts by mass of the ethylene resin.

Examples of the lubricant include a fatty acid amide compound and a phosphite compound. Specific examples of the fatty acid amide compound include oleamide, erucamide, stearamide, behenamide, ethylenebisoleamide, and ethylene bisstearamide. Examples of the phosphite compound include alkyl phosphites, such as decyl phosphite; alkyl acid phosphates, such as decyl acid phosphate: aryl acid phosphates, such as phenyl acid phosphate: trialkyl phosphates, such as trihexyl phosphate: triaryl phosphates, such as tricresyl phosphate; and zinc dithiophosphate. The content of the lubricant is preferably 1 part by mass or less, more preferably 0.05 parts by mass to 0.5 parts by mass, relative to 100 parts by mass of the ethylene resin.

The silane coupling agent is added in order to enhance the adhesion of the encapsulant sheet to a light-receiving-surface protector, a lower protector (backsheet), and a solar cell element. Examples of the silane coupling agent include γ-chloropropyltrimethoxysilane, vinyltrichlorosilane, vinyltriethoxysilane, vinyl-tris(β-methoxyethoxy)silane, γ-methacryloxypropyltrimethoxysilane, β-(3,4-ethoxycyclohexyl)ethyl-trimethoxysilane, γ-glycidoxypropyltrimethoxysilane, vinyltriacetoxysilane, γ-mercaptopropyltrimethoxysilane, γ-aminopropyltrimethoxysilane, N-β-(aminoethyl)-γ-aminopropyltrimethoxysilane, allyltrimethoxysilane, allyltriethoxysilane, allyltriisopropoxysilane, vinylethyltrimethoxysilane, vinylethyltriethoxysilane, vinylpropyltrimethoxysilane, vinylbutyltrimethoxysilane, vinylbutyltriethoxysilane, vinylbutyltriisopropoxysilane, vinylpentyltrimethoxysilane, vinylhexyltrimethoxysilane, vinylheptyltrimethoxysilane, and vinyloctyltrimethoxysilane. These silane coupling agents may be used either individually or in combination. As the silane coupling agent, γ-methacryloxypropyltrimethoxysilane, allyltrimethoxysilane, allyltriethoxysilane, allyltriisopropoxysilane, vinylethyltrimethoxysilane, vinylethyltriethoxysilane, vinylpropyltrimethoxysilane, vinylbutyltrimethoxysilane, vinylbutyltriethoxysilane, or vinylbutyltriisopropoxysilane is preferable, and vinylbutyltrimethoxysilane is more preferable.

The lower limit of the content of the silane coupling agent is preferably 0.001 part by mass, more preferably 0.01 parts by mass, and even more preferably 0.1 parts by mass, relative to 100 parts by mass of the ethylene resin. The upper limit of the content of the silane coupling agent is preferably 5 parts by mass, more preferably 1.0 part by mass, and even more preferably 0.5 parts by mass.

Examples of the light stabilizer to be used in the present invention include bis(2,2,6,6-tetramethyl-4-piperidyl) sebacate, bis(1-undecanoxy-2,2,2,6-tetramethylpiperidin-4-yl)carbonate, and hindered amine compounds having a pKa of 6.0 to 8.0 and a molecular weight of 2000 to 10000. Examples of the hindered amine compounds having a pKa of 6.0 to 8.0 and a molecular weight of 2000 to 10000 include copolymers of 2,2,6,6-tetramethyl-4-piperidineamine with an α-alkene having 20 to 24 carbon atoms. The content of the light stabilizer is preferably 0.05 parts by to 1 part by mass, more preferably 0.1 parts by mass to 0.5 parts by mass, and even more preferably 0.15 parts by mass to 0.3 parts by mass, relative to 100 parts by mass of the ethylene resin.

Commercially available products of the hindered amine compounds having a pKa of 6.0 to 8.0 and a molecular weight of 2000 to 10000 include Tinuvin 622 and Uvinul 5050H (produced by BASF). Light stabilizers may be used either individually or in combination.

### [Encapsulant Sheet for a Solar Cell]

The encapsulant sheet of the present invention is a sheet formed of a material comprising at least one ethylene resin selected from the group consisting of an ethylene-α-olefin copolymer, an ethylene homopolymer, and an ethylene-unsaturated ester copolymer, wherein the volume resistivity value of the material measured at 23° C. is 1×10¹⁷ Ω·cm or more and the average luminous transmittance of the material within a wavelength of from 400 nm to 1200 nm is 91% or more.

The volume resistivity value of the sheet-forming material measured at 23° C. is preferably 1×10¹⁷ Ω·cm or more, more preferably 2×10 Ω·cm or more. The volume resistivity value is determined in the following procedure. A sample sheet formed of a sheet-forming material is placed on a large diameter electrode for a plate sample (for example, SME-8310, manufactured by DKK-TOA CORPORATION), a voltage of 500 V is applied to it at 23° C., and the resistance value thereof is measured with a digital insulation resistance tester (for example, DSM-8103, manufactured by DKK-TOA CORPORATION). Then, a volume resistivity value is calculated on the basis of the resistance value. The volume resistivity value to be measured at 23° C. can be adjusted by varying the physical property values (HL110, density, Vicat softening point, etc.) of the ethylene resin, and the types of additives (the compound (A), the crosslinking agent, the crosslinking aid, etc.) and the contents thereof.

The average luminous transmittance can be adjusted by varying the physical property values (HL110, density. Vicat softening point, etc.) of the ethylene resin, and the types of additives (the compound (A), the crosslinking agent, the crosslinking aid, etc.) and the contents thereof.

The average luminous transmittance is determined by the following method. Then, a sheet-forming material is sandwiched with a surface-processed polyethylene terephthalate sheet (for example, SP PET-7501BU, produced by PANAC Corporation) on its surface-processed surfaces, and then is pressed for 5 minutes at a pressure of 2 MPa with a hot pressing machine at 100° C. and then cooled for 5 minutes with a cold pressing machine at 30° C., and then pressed for 20 minutes at a pressure of 2 MPa with a hot pressing machine at 150° C. and then cooled for 5 minutes with a cold pressing machine at 30° C., and thus is shaped into a sheet about 500 μm thick. A light transmission spectrum along the thickness direction of the sheet is measured with a spectrophotometer (UV-3150 manufactured by Shimadzu Corporation), and then an average value of the light transmittance within the wavelength range from 400 nm to 1200 nm is calculated.

Examples of the method for processing the encapsulant sheet of the present invention include a method of processing a sheet-forming material into an encapsulant sheet using a sheet processing machine, such as T-die extruder and a calendering machine.

It is also permitted to melt-knead an ethylene resin and, if necessary, various additives beforehand to obtain a sheet-forming material, and then supply the sheet-forming material to a sheet processing machine and process it into an encapsulant sheet. When adding the compound (A), it is also permitted to supply pellets prepared by attaching the compound (A) to the surface of pellets of an ethylene resin, and, if necessary, additives to a sheet processing machine and then process them into an encapsulant sheet.

### [Solar Cell]

The encapsulant sheet of the present invention is used as a constituent of a solar cell. The solar cell of the present invention comprises a light-receiving-surface protector, a lower protector, a solar cell element, and at least one encapsulant sheet of the present invention of at least one sheet. Use of the encapsulant sheet of the present invention can afford a solar cell in which a solar cell element is encapsulated with the encapsulant sheet between the light-receiving-surface protector and the lower protector. Examples of the light-receiving-surface protector include a protector made of a translucent material such as glass and plastics. Examples of the lower protector include protectors formed of such materials as plastics, ceramics, stainless steel, and aluminum.

Examples of the method for producing a solar cell include a method comprising step (A) of disposing a light-receiving-surface protector, a lower protector, a solar cell element, and at least one encapsulant sheet in a prescribed arrangement, and step (B) of encapsulating the solar cell element with the at least one encapsulant sheet.

In the step (A), it is preferred to dispose a light-receiving-surface protector/encapsulant sheet/solar cell element/encapsulant sheet/lower protector in this order.

The solar cell is assembled in the following manner, for example. On each side of a planar element such as a silicon substrate, one sheet of the encapsulant sheet of the present invention is disposed. The light-receiving-surface protector is put on one side of the solar cell element with the encapsulant sheets and the lower protector is put on the other side, and the resulting combination is put into a vacuum laminator and the inside of the vacuum laminator is brought into a vacuum state (a pressure equal to or lower than 140 Pa), and then it is heated to a temperature at the encapsulant sheet melts. The encapsulant sheets are melted to some extent, and then pressure is applied while heating is continued. By the heating under vacuum and the heating under heating, the ethylene resin contained in the individual encapsulant sheets is crosslinked in itself and the ethylene resin in the encapsulant sheet disposed on one side of the solar cell element with the encapsulant sheets and the ethylene resin contained in the encapsulant sheet disposed on the other side of the solar cell element are crosslinked together. When the encapsulant sheets contain a silane coupling agent, the silane coupling agent contained in one encapsulant sheet is reacted with the light-receiving-surface protector, the silane coupling agent contained in the other encapsulant sheet is reacted with the lower protector, and the silane coupling agents contained in both the encapsulant sheets are reacted with the solar cell element as a result of the heating, so that one of the encapsulant sheet is bonded to the light-receiving-surface protector, the other encapsulant sheet is bonded to the lower protector, and the encapsulant sheets are bonded to the solar cell element.

Preferably, the heating temperature is 100° C. to 200° C. The pressurizing method may be, for example, a method of adding a pressure of 1.0×10³ Pa to 5.0×10⁷ Pa by using a double vacuum chamber-type vacuum laminator.

Examples of the solar cell element include P type single crystal silicon, N type single crystal silicon, polycrystalline silicon, amorphous silicone, and compound type elements. Since the encapsulant sheet of the present invention is capable of enhancing the conversion efficiency of solar cells and also capable of well suppressing the PID phenomenon, it can be used suitably also for a solar cell comprising an N type single crystal silicon cell as a power generation element.

A sheet-forming material in which the ethylene resin comprises an ethylene-α-olefin copolymer (Y) having a ratio (HL110) of the heat of fusion within a temperature range of from 20° C. to 110° C. to the total heat of fusion measured by differential scanning calorimetry of less than 85% preferably comprises 0.001 parts by mass to 2 parts by mass of a dialkyl peroxide and 0.001 parts by mass to 2 parts by mass of a crosslinking aid. From the viewpoint of achieving a higher conversion efficiency of a solar cell and the viewpoint of more effectively suppressing the PID phenomenon, the mass ratio of the content of the crosslinking aid to the content of the crosslinking agent is preferably from 0.3 to 2.5, more preferably from 0.4 to 1.5. It is preferred from the viewpoint of more effectively suppressing the PID phenomenon that the lower limit of the content of the compound (A) is 0.001 parts by mass, more preferably 0.01 parts by mass, even more preferably 0.1 parts by mass, and the upper limit of the content of the compound (A) is preferably 5 parts by mass, more preferably 0.5 parts by mass. It is noted that the content of the ethylene resin is taken as 100 parts by mass.

Preferably, a sheet-forming material in which the ethylene resin comprises an ethylene-unsaturated ester copolymer comprises 0.001 parts by mass to 2 parts by mass of a dialkyl peroxide and also comprises 0.001 parts by mass to 2 parts by mass of a crosslinking aid. From the viewpoint of more effectively suppressing the PID phenomenon, the mass ratio of the content of the crosslinking aid having four or more (meth)acryloyl groups to the content of the dialkyl peroxide is preferably 0.3 to 1.2, more preferably 0.6 to 1.1. It is preferred from the viewpoint of more effectively suppressing the PID phenomenon that the lower limit of the content of the compound (A) is 0.001 parts by mass, more preferably 0.01 parts by mass, even more preferably 0.1 parts by mass, and the upper limit of the content of the compound (A) is preferably 5 parts by mass, more preferably 0.5 parts by mass. It is noted that the content of the ethylene resin is taken as 100 parts by mass.

### EXAMPLES

The present invention is described in more detail below by Examples.

[Volume Resistivity Value (Unit: Ω·cm)]

A sample sheet was placed on a large diameter electrode for a plate sample (SME-8310, manufactured by DKK-TOA CORPORATION), a voltage of 500 V was applied to it and, after one minute, the resistance value thereof was measured with a digital insulation resistance tester (DSM-8103, manufactured by DKK-TOA CORPORATION). A volume resistivity value was calculated on the basis of the resistance value.

### [Average Luminous Transmittance (Unit: %)]

Then, a sample of the kneaded mixture was sandwiched with a surface-processed polyethylene terephthalate sheet (SP PET-7501BU, produced by PANAC Corporation) on its surface-processed surfaces, and then was pressed for 5 minutes at a pressure of 2 MPa with a hot pressing machine at 100° C. and then cooled for 5 minutes with a cold pressing machine at 30° C., and then pressed for 20 minutes at a pressure of 2 MPa with a hot pressing machine at 150° C. and then cooled for 5 minutes with a cold pressing machine at 30° C., and thus was shaped into a sheet about 500 μm thick. A light transmission spectrum along the thickness direction of the sheet was measured with a spectrophotometer (UV-3150 manufactured by Shimadzu Corporation), and then an average value of the light transmittance within the wavelength range from 400 nm to 1200 nm was calculated.

[Average Particle Diameter (Unit: μm)]

The average particle diameter of silicon dioxide was calculated by the following method.

The average particle diameter of silicon dioxide was calculated by the following method. Silicon dioxide was added to ethanol and was dispersed with a homogenizer for 10 minutes. The dispersion liquid was irradiated with laser beams, which were thereby scattered, and the scattering light was collected with a lens. The diffraction pattern formed on the focal plane was measured as a particle size distribution on volume basis by means of a Microtrac particle size analyzer (MT-3000EX II manufactured by Nikkiso Co., Ltd.). The median particle diameter of the resulting particle size distribution was taken as an average particle size.

[Melt Flow Rate (MFR, Unit: g/10 Minutes)]

The melt flow rate of an ethylene-α-olefin copolymer and an ethylene-methyl methacrylate copolymer was measured at a temperature of 190° C. and a load of 21.18 N in accordance with Method A specified in JIS K7210-1995.

### [Molecular Weight Distribution (Mw/Mn)]

The polystyrene-equivalent weight average molecular weight (Mw) and the polystyrene-equivalent number average molecular weight (Mn) of a copolymer were measured using gel permeation chromatography (GPC) under the following conditions (1) to (8), and then molecular weight distribution (Mw/Mn) was determined.

(1) Instrument: Waters 150C manufactured by Waters Corporation
(2) Separation column: TOSOH TSKgel GMH-HT
(3) Measurement temperature: 140° C.
(4) Carrier: orthodichlorobenzene
(5) Flow rate: 1.0 mL/min
(6) Injection amount: 500 μL.
(7) Sample concentration: 5 mg/5 ml in orthodichlorobenzene
(8) Detector: differential refraction
[Ignition Loss (unit: %)]

The ignition loss of silicon dioxide was measured in accordance with the method defined in JIS K1150-1994 using a sample dried at about 150° C. for 2 hours under vacuum.

### [Vicat Softening Point (Unit: ° C.)]

The Vicat softening point was measured in accordance with the method specified in JIS K7206-1979.

[Ratio of the Heat of Fusion within a Temperature Range of 20° C. to 110° C. to the Total Heat of Fusion (HL110, Unit: %)]

HL110 was measured using a differential scanning calorimeter (Diamond® DSC manufactured by PerkinElmer). A sample (4 to 10 mg in weight) was put into an aluminum pan, held at 150° C. for 5 minutes, then cooled from 150° C. to 20° C. at a temperature ramp-down rate of 5° C./minute, held at 20° C. for 2 minutes, then heated from 20° C. to 150° C. at a temperature ramp-up rate of 5° C./minute, and the amount of heat absorbed was measured during the heating, and a melting curve was produced. On the melting curve, the point corresponding to the temperature at which the curve flattens and the point corresponding to a temperature of 20° C. were connected by a straight line, which was defined as a baseline. Then, the total area of the region surrounded by the baseline and the melting curve (the total area corresponds to the total heat of fusion) and the area of the region from 20° C. to 110° C. (this area corresponds to the heat of fusion in the range of 20° C. to 110° C.) were determined, and then HL110 was calculated from the following formula:

HL110(%)=(the heat of fusion at 20° C. to 110C)/(the total heat of fusion)×100

### [Initial Output of Solar Cell (Unit: W)]

A sample was sandwiched with a surface-processed polyethylene terephthalate sheet (SP PET-7501BU, produced by PANAC Corporation) on its surface-processed surfaces, and then was pressed for 5 minutes at a pressure of 2 MPa with a hot pressing machine at 100° C. and then cooled for 5 minutes with a cold pressing machine at 30° C., and thus was shaped into a sheet about 500 μm thick.

On 3.2 mm-thick white platy heat-processed glass, one piece of the aforementioned sheet, a photovoltaic cell (N type single crystal silicon, 6 inches, 3 bus bar type, cell efficiency: 19.0%), another piece of the aforementioned sheet, and a backsheet (SPE-35, produced by SFC) were stacked in this order and then degassed for 5 minutes under heating at 145° C. by use of a vacuum laminator, followed by pressing under vacuum for 25 minutes, and thus a solar cell was obtained. According to JIS C8914, the maximum output of the solar cell was measured and it was taken as the initial output (unit: W) of the solar cell.

[Output Retention after PID Test (Unit: %)]

The solar cell obtained above was placed in a thermo-hygrostat having a in-bath temperature of 60° C. and a relative humidity of 85% RH and a voltage was applied with the glass side of the solar cell immersed in water in the water bath. A negative electrode was connected to the line of the photovoltaic cell and a line of the positive electrode was connected to the module frame side, and then 1000 V or a direct current voltage was applied. The voltage was applied in this state for 96 hours and then the maximum output of the solar cell was measured and the measurement obtained was taken as the output after a PID test.

The output retention (unit: %) after the PID test was calculated from the following formula.

Output retention after PID test (unit: %)=(output after PID test)/(initial output of solar cell)×100

[Activation Energy of Flow (Ea, Unit: kJ/Mol)]

A shift factor (aT) at each temperature (T) of 130° C., 150° C., 170° C., and 190° C. was determined by superposing melting complex viscosity (unit: Pa·sec)-angular frequency (unit: rad/sec) curves of an olefin polymer at the respective temperatures (T, unit: ° C.) on melting complex viscosity-angular frequency curve of the olefin polymer at 190° C. on the basis of the temperature-time superposition principle about every melting complex viscosity-angular frequency curve at each temperature (T). Then, a linear approximate equation (the following formula (II)) of [ln(aT)] and [1/(T+273.16)] was calculated by the least squares method from the temperatures (T) and the shift factors (aT) at the respective temperatures (T). Subsequently, Ea was calculated from the gradient m of the primary expression and the following formula (III).

ln(aT)=m(1/(T+273.16))+n (II)

Ea=|0.008314×m| (III)

aT: shift factor

Ea: activation energy of flow (unit: kJ/mol)

T: temperature (unit: ° C.)

In the calculation was used commercially available calculation software Rhios V.4.4.4 produced by Rheometrics.

### [Synthesis of Ethylene-1-Butene Copolymer (PE-1)]

### (1) Preparation of Solid Catalyst Component

Into a reactor equipped with a stirrer and purged with nitrogen were charged 2.8 kg of silica heat treated at 300° C. under a nitrogen flow (Sylopol 948 produced by Davison Co., Ltd.: 50% average particle diameter=55 μm: pore=1.67 ml/g; specific surface area=325 m²/g) and 24 kg of toluene, which were then stirred. After cooling to 5° C., a mixed solution of 0.9 kg of 1,1,1,3,3,3-hexamethyldisilazane and 1.4 kg of toluene was dropped over 30 minutes with the temperature in the reactor kept at 5° C. After the completion of the dropping, the mixture was stirred at 5° C. for 1 hour and then heated to 95° C. and stirred at 95° C. for 3 hours, followed by filtration of the contents. Then, the resulting solid product was washed with 20.8 kg of toluene six times. Thereafter, 7.1 kg of toluene was added to form a slurry, which was then allowed to stand overnight.

Into the slurry obtained above were fed 1.73 kg of a hexane solution of diethylzinc (diethylzinc concentration: 50% by weight) and 1.02 kg of hexane, and the resultant was stirred. Then, after cooling to 5° C. a mixed solution of 0.78 kg of 3,4,5-trifluorophenol and 1.44 kg of toluene was dropped over 60 minutes with the temperature in the reactor kept at 5° C. After the completion of the dropping, the mixture was stirred at 5° C. for 1 hour, then the temperature was raised to 40° C., and this was stirred at 40° C. for 1 hour. Then, the mixture was cooled to 22° C., and 0.11 kg of water was dropped over 1.5 hours with the temperature in the reactor kept at 22° C. After the completion of the dropping, the mixture was stirred at 22° C. for 1.5 hours, then, the temperature was raised to 40° C., the mixture was stirred at 40° C. for 2 hours, further, the temperature was raised to 80° C., and the mixture was stirred at 80° C. for 2 hours. After the stirring, at room temperature, the supernatant was extracted to a remaining amount of 16 L, 11.6 kg of toluene was fed therein, then the temperature was raised to 95° C., and the mixture was stirred for 4 hours. After stirring, at room temperature, the supernatant was extracted, whereby a solid product was obtained. The resulting solid product was washed with 20.8 kg of toluene four times and with 24 liters of hexane three times. Subsequent drying afforded a solid catalyst constituent. The solid catalyst component is hereafter called “solid catalyst component (1).”

### (2) Preparation of Preliminarily Polymerized Catalyst Component

A nitrogen-purged, 210-liter autoclave equipped with a stirrer was charged with 80 liters of butane and then 34.5 mmol of racemic-ethylenebis(1-indenyl)zirconium diphenoxide was charged, and the autoclave was heated up to 50° C., followed by stirring for two hours. Then, the inside of the autoclave was cooled down to 30° C. to stabilize the system. Subsequently, ethylene was charged in an amount corresponding to 0.03 MPa of a gas phase pressure within the autoclave, and 0.7 kg of the solid catalyst component (1) was charged, and then 140 mmol of triisobutylaluminum was charged to initiate polymerization. After 30 minutes had passed while ethylene was fed continuously at 0.7 kg/hr, the temperature was raised to 50° C. and ethylene and hydrogen were fed continuously at 3.5 kg/hr and 10.2 liters (volume at normal temperature and normal pressures)/hr, respectively, and thus prepolymerization was carried out for 4 hours in total. After the completion of the polymerization, ethylene, butane, hydrogen gas, and so on were purged and the remaining solid was vacuum-dried at room temperature. Thus, a prepolymerized catalyst component in which 15 g of polyethylene was prepolymerized per gram of the solid catalyst component (1) was prepared.

### (3) Production of PE-1

Using the preliminarily polymerized catalyst component prepared as described above, copolymerization of ethylene with 1-butene was performed in an autoclave with an internal volume of 3 liters equipped with a stirrer, and thus a polymer powder was obtained. Regarding the polymerization condition, 611 g of 1-butene was fed and polymerization was performed in a butane slurry state at a polymerization temperature of 60° C., an ethylene partial pressure of 1.0 MPa, and a molar ratio of hydrogen to ethylene of 5.5%. In order to make the gas composition constant, ethylene and hydrogen were continuously supplied during the polymerization. The polymerization time was limited to 3 hours. Thus, an ethylene-1-butene copolymer (PE-1) was prepared. The copolymer (PE-1) had long chain branches, and it had an MFR of 22 g/10 minutes, a density of 904 kg/m³, and an Ea of 57 kJ/mol. The content of the monomer units derived from ethylene was 11% by mass, and the content of the monomer units derived from 1-butene was 89% by mass. The Vicat softening point was 62° C. and the HL110 was 99%.

### Example 1

An ethylene-1-butene copolymer (PE-1) in an amount of 100 parts by mass, 0.12 parts by mass of γ-methacryloxypropyltrimethoxysilane (Silquest (registered trademark) A-174, produced by Momentive Performance Materials Japan LLC: silane coupling agent), 0.4 parts by mass of tert-butylperoxy-2-ethylhexyl carbonate (PERBUTYL (registered trademark) E, produced by NOF Corporation, one-hour half-life temperature: 121° C.: crosslinking agent), and 0.9 parts by mass of triallyl isocyanurate (TAIC (registered trademark), produced by Tokyo Chemical Industry Co., Ltd.; crosslinking aid), were kneaded for 5 minutes with a Labo Plastomill. Then, a sample of the kneaded mixture was sandwiched with a surface-processed polyethylene terephthalate sheet (SP PET-7501BU, produced by PANAC Corporation) on its surface-processed surfaces, and then was pressed for 5 minutes at a pressure of 2 MPa with a hot pressing machine at 100° C. and then cooled for 5 minutes with a cold pressing machine at 30° C., and then pressed for 20 minutes at a pressure of 2 MPa with a hot pressing machine at 150° C. and then cooled for 5 minutes with a cold pressing machine at 30° C., and thus was shaped into a sheet about 500 μm thick. The volume resistivity value and the average luminous transmittance of the resulting sheet were measured and the results are shown in Table 1. For a solar cell prepared using a sample of the mixture kneaded with the Labo Plastomill, an initial conversion efficiency and an output retention after a PID test were measured, and the results are shown in Table 1.

### Example 2

An ethylene-1-butene copolymer (PE-1) in an amount of 100 parts by mass, 0.12 parts by mass of γ-methacryloxypropyltrimethoxysilane (Silquest (registered trademark) A-174; silane coupling agent), 0.4 parts by mass of tert-butylperoxy-2-ethylhexyl carbonate (PERBUTYL (registered trademark) E; crosslinking agent), 0.9 parts by mass of triallyl isocyanurate (TAIC (registered trademark): crosslinking aid), and 0.2 parts by mass of non-calcined amorphous silicon dioxide (CARPLEX (registered trademark) #67, produced by Evonik Degussa Japan Co., Ltd., average particle diameter: 8 μm, ignition loss: 4.0%) were kneaded with a Labo Plastomill for 5 minutes, and then a sheet was prepared and was evaluated in the same manner as in Example 1. The evaluated results are shown in Table 1.

### Example 3

An ethylene-methyl methacrylate copolymer (EMMA-1, produced by Sumitomo Chemical Co., Ltd., Acryft (registered trademark) WK402, MFR: 20 g/10 minutes, content of monomer units derived from ethylene: 75% by mass, content of monomer units derived from methyl methacrylate: 25% by mass, Ea: 114 kJ/mol, Mw/Mn: 3.1; Vicat softening point: 42° C.; HL110: 100%) in an amount of 100 parts by mass, 0.12 parts by mass of γ-methacryloxypropyltrimethoxysilane (Silquest (registered trademark) A-174; silane coupling agent), 1.0 part by mass of 2,5-dimethyl-2,5-di(tert-butylperoxy)hexane (Perhexa (registered trademark) 25B, produced by NOF Corporation, one-hour half-life temperature: 138.1° C.: crosslinking agent), 0.5 parts by mass of triallyl isocyanurate (TAIC (registered trademark); crosslinking aid), 1.0 part by mass of dipentaerythritol hexaacrylate (product name: A-DPH, produced by Shin-Nakamura Chemical Co., Ltd.; crosslinking aid), and 0.2 parts by mass of non-calcined amorphous silicon dioxide (CARPLEX (registered trademark) #67) were kneaded with a Labo Plastomill for 5 minutes, and then a sheet was prepared and was evaluated in the same manner as in Example 1. The evaluated results are shown in Table 2.

### Example 4

A sheet was prepared and was evaluated in the same manner as in Example 3 except that the amount of 2,5-dimethyl-2,5-di(tert-butylperoxy)hexane was changed to 0.6 parts by mass and the amount of dipentaerythritol hexaacrylate was changed to 0.6 parts by mass. The evaluated results are shown in Table 2.

### Example 5

An ethylene-1-hexene copolymer (PE-3, produced by Sumitomo Chemical Co., Ltd., SUMIKATHENE E FV401, MFR: 3.1 g/10 minutes, density: 903 kg/m³, Ea: 35 kJ/mol, content of monomer units derived from ethylene: 83% by mass; content of monomer units derived from 1-hexene: 12% by mass; Vicat softening point: 83° C.; HL110: 76%) in an amount of 100 parts by mass, 0.12 parts by mass of γ-methacryloxypropyltrimethoxysilane (Silquest (registered trademark) A-174; silane coupling agent), 1.0 part by mass of 2,5-dimethyl-2,5-di(tert-butylperoxy)hexane (Perhexa (registered trademark) 25B; crosslinking agent), 0.5 parts by mass of triallyl isocyanurate (TAIC (registered trademark): crosslinking aid), and 0.2 parts by mass of non-calcined amorphous silicon dioxide (CARPLEX (registered trademark) #67) were kneaded with a Labo Plastomill for 5 minutes, and then a sheet was prepared and was evaluated in the same manner as in Example 1. The evaluated results are shown in Table 2.

### Comparative Example 1

A sheet was prepared and was evaluated in the same manner as in Example 1 except that 100 parts by mass of an ethylene homopolymer (PE-2, produced by Sumitomo Chemical Co., Ltd., SUMIKATHENE L405, MFR: 3.7 g/10 minutes, density: 924 kg/m³, Ea: 66 kJ/mol; Vicat softening point: 95° C.; HL110: 88%) was used instead of the ethylene-1-butene copolymer (PE-1). The evaluated results are shown in Table 1.

### Comparative Example 2

An ethylene-methyl methacrylate copolymer (EMMA-1) in an amount of 100 parts by mass, 0.12 parts by mass of γ-methacryloxypropyltrimethoxysilane (Silquest (registered trademark) A-174; silane coupling agent), 0.4 parts by mass of tert-butylperoxy-2-ethylhexyl carbonate (PERBUTYL (registered trademark) E: crosslinking agent), and 0.9 parts by mass of triallyl isocyanurate (TAIC (registered trademark): crosslinking aid), were kneaded with a Labo Plastomill for 5 minutes, and then a sheet was prepared and was evaluated in the same manner as in Example 1. The evaluated results are shown in Table 2.

### Comparative Example 3

An ethylene-methyl methacrylate copolymer (EMMA-1) in an amount of 100 parts by mass, 0.12 parts by mass of γ-methacryloxypropyltrimethoxysilane (Silquest (registered trademark) A-174; silane coupling agent), 0.4 parts by mass of tert-butylperoxy-2-ethylhexyl carbonate (PERBUTYL (registered trademark) E: crosslinking agent), 0.9 parts by mass of triallyl isocyanurate (TAIC (registered trademark); crosslinking aid), and 0.2 parts by mass of non-calcined amorphous silicon dioxide (CARPLEX (registered trademark) #67) were kneaded with a Labo Plastomill for 5 minutes, and then a sheet was prepared and was evaluated in the same manner as in Example 1. The evaluated results are shown in Table 2.

### Comparative Example 4

An ethylene-1-hexene copolymer (PE-3) in an amount of 100 parts by mass, 0.12 parts by mass of γ-methacryloxypropyltrimethoxysilane (Silquest (registered trademark) A-174; silane coupling agent), 0.4 parts by mass of tert-butylperoxy-2-ethylhexyl carbonate (PERBUTYL (registered trademark) E: crosslinking agent), and 0.9 parts by mass of triallyl isocyanurate (TAIC (registered trademark); crosslinking aid), were kneaded with a Labo Plastomill for 5 minutes, and then a sheet was prepared and was evaluated in the same manner as in Example 1. The evaluated results are shown in Table 3.

### Comparative Example 5

An ethylene-based copolymer (PE-4, produced by Sumitomo Chemical Co., Ltd., EXCELEN VL EUL830. MFR: 20 g/10 minutes, density: 895 kg/m³; Vicat softening point: 47° C.; HL110: 81%) in an amount of 100 parts by mass, 0.12 parts by mass of γ-methacryloxypropyltrimethoxysilane (Silquest (registered trademark) A-174; silane coupling agent), 0.4 parts by mass of tert-butylperoxy-2-ethylhexyl carbonate (PERBUTYL (registered trademark) E; crosslinking agent), and 0.9 parts by mass of triallyl isocyanurate (TAIC (registered trademark): crosslinking aid) were kneaded with a Labo Plastomill for 5 minutes, and then a sheet was prepared and was evaluated in the same manner as in Example 1. The evaluated results are shown in Table 3.

### Comparative Example 6

An ethylene-methyl methacrylate copolymer (EMMA-1) in an amount of 100 parts by mass, 0.12 parts by mass of γ-methacryloxypropyltrimethoxysilane (Silquest (registered trademark) A-174; silane coupling agent), 1.0 part by mass of tert-butylperoxy-2-ethylhexyl carbonate (PERBUTYL (registered trademark) E; crosslinking agent), 0.5 parts by mass of triallyl isocyanurate (TAIC (registered trademark); crosslinking aid), 1.0 part by mass of dipentaerythritol hexaacrylate (product name: A-DPH, produced by Shin-Nakamura Chemical Co., Ltd.: crosslinking aid), and 0.2 parts by mass of non-calcined amorphous silicon dioxide (CARPLEX (registered trademark) #67) were kneaded with a Labo Plastomill for 5 minutes, and then a sheet was prepared and was evaluated in the same manner as in Example 1. The evaluated results are shown in Table 3.

### Comparative Example 7

An ethylene-methyl methacrylate copolymer (EMMA-1) in an amount of 100 parts by mass, 0.12 parts by mass of γ-methacryloxypropyltrimethoxysilane (Silquest (registered trademark) A-174; silane coupling agent), 1.0 part by mass of 2,5-dimethyl-2,5-di(tert-butylperoxy)hexane (Perhexa (registered trademark) 25B; crosslinking agent), 0.5 parts by mass of triallyl isocyanurate (TAIC (registered trademark); crosslinking aid), and 0.2 parts by mass of non-calcined amorphous silicon dioxide (CARPLEX (registered trademark) #67) were kneaded with a Labo Plastomill for 5 minutes, and then a sheet was prepared and was evaluated in the same manner as in Example 1. The evaluated results are shown in Table 3.

TABLE 1

| | | | | Comparative |
|---|---|---|---|---|
| | | Example 1 | Example 2 | Example 1 |
| Ethylene resin | | PE-1 | PE-1 | PE-2 |
| Compound (A) | | Absent | Carplex #67 | Absent |
| Content of | pbm* | — | 0.2 | — |
| compound (A) | | | | |
| Compound (B) | | Absent | Absent | Absent |
| Content of | pbm* | — | — | — |
| compound (B) | | | | |
| Other ingredients | | A-174/ | A-174/ | A-174/ |
| | | PERBUTYL | PERBUTYL | PERBUTYL |
| | | E/TAIC | E/TAIC | E/TAIC |
| Contents of other | pbm* | 0.12/0.4/0.9 | 0.12/0.4/0.9 | 0.12/0.4/0.9 |
| ingredients | | | | |
| Vicat softening | ° C. | 62 | 62 | 95 |
| point | | | | |
| HL110 | % | 99 | 99 | 88 |
| Volume resistivity | Ω · cm | 2.7 × 10¹⁷ | 3.9 × 10¹⁷ | 2.8 × 10¹⁷ |
| value | | | | |
| Average luminous | % | 91.2 | 91.2 | 84.8 |
| transmittance | | | | |
| Initial output of | W | 4.32 | 4.26 | 4.14 |
| solar cell | | | | |
| Output retention | % | 100 | 100 | 100 |
| after PID test | | | | |

*pbm: parts by mass

TABLE 2

| | | | | | Comparative | Comparative |
|---|---|---|---|---|---|---|
| | | Example 3 | Example 4 | Example 5 | Example 2 | Example 3 |
| Ethylene resin | | EMMA-1 | EMMA-1 | PE-3 | EMMA-1 | EMMA-1 |
| Compound (A) | | Carplex #67 | Carplex #67 | Carplex #67 | Absent | Carplex #67 |
| Content of | pbm* | 0.2 | 0.2 | 0.2 | — | 0.2 |
| compound (A) | | | | | | |
| Compound (B) | | Perhexa | Perhexa | Perhexa | Absent | Absent |
| | | 25B/A-DPH | 25B/A-DPH | 25B | | |
| Content of | pbm* | 1.0/1.0 | 0.6/0.6 | 1.0 | — | — |
| compound (B) | | | | | | |
| Other ingredients | | A-174/TAIC | A-174/TAIC | A-174/TAIC | A-174/ | A-174/ |
| | | | | | PERBUTYL E/ | PERBUTYL E/ |
| | | | | | TAIC | TAIC |
| Contents of | pbm* | 0.12/0.5 | 0.12/0.5 | 0.12/0.5 | 0.12/0.4/0.9 | 0.12/0.4/0.9 |
| other ingredients | | | | | | |
| Vicat softening point | ° C. | 42 | 42 | 83 | 42 | 42 |
| HL110 | % | 100 | 100 | 76 | 100 | 100 |
| Volume resistivity | Ω · cm | 2.2 × 10¹⁷ | 2.9 × 10¹⁷ | 3.8 × 10¹⁷ | 1.7 × 10¹⁵ | 2.0 × 10¹⁶ |
| value | | | | | | |
| Average luminous | % | 92.2 | 92.3 | 91.0 | 92.3 | 92.3 |
| transmittance | | | | | | |
| Initial output of | W | 4.29 | 4.28 | 4.20 | 4.26 | 4.24 |
| solar cell | | | | | | |
| Output retention | % | 99 | 99 | 100 | 85 | 85 |
| after PID test | | | | | | |

*pbm: parts by mass

TABLE 3

| | | Comparative | Comparative | Comparative | Comparative |
|---|---|---|---|---|---|
| | | Example 4 | Example 5 | Example 6 | Example 7 |
| Ethylene resin | | PE-3 | PE-4 | EMMA-1 | EMMA-1 |
| Compound (A) | | Absent | Absent | Carplex #67 | Carplex #67 |
| Content of | pbm* | — | — | 0.2 | 0.2 |
| compound (A) | | | | | |
| Compound (B) | | Absent | Absent | A-DPH | Perhexa 25B |
| Content of | pbm* | — | — | 1.0 | 1.0 |
| compound (B) | | | | | |
| Other ingredients | | A-174/ | A-174/ | A-174/ | A-174/TAIC |
| | | PERBUTYL | PERBUTYL | PERBUTYL | |
| | | E/TAIC | E/TAIC | E/TAIC | |
| Contents of other | pbm* | 0.12/0.4/0.9 | 0.12/0.4/0.9 | 0.12/1.0/0.5 | 0.12/0.5 |
| ingredients | | | | | |
| Vicat softening point | ° C. | 83 | 47 | 42 | 42 |
| HL110 | % | 76 | 81 | 100 | 100 |
| Volume resistivity | Ω · cm | 8.8 × 10¹⁶ | 5.9 × 10¹⁶ | 3.4 × 10¹⁶ | 7.6 × 10¹⁶ |
| value | | | | | |
| Average luminous | % | 90.2 | 88.8 | 92.1 | 92.1 |
| transmittance | | | | | |
| Initial output of solar | W | 4.15 | 4.16 | 4.24 | 4.24 |
| cell | | | | | |
| Output retention after | % | 98 | 88 | 85 | 87 |
| PID test | | | | | |

*pbm: parts by mass

1. A solar cell encapsulant sheet formed of a material comprising at least one ethylene resin selected from the group consisting of an ethylene-α-olefin copolymer, an ethylene homopolymer, and an ethylene-unsaturated ester copolymer, wherein the volume resistivity value of the material measured at 23° C. is 1×10¹⁷ Ω·cm or more and the average luminous transmittance of the material within a wavelength range of from 400 nm to 1200 nm is 91% or more.

2. The solar cell encapsulant sheet of claim 1, wherein the material further comprises 0.001 parts by mass to 5 parts by mass of at least one compound (A) selected from the group consisting of silicon dioxide, zeolite, a bismuth oxide based compound, an antimony oxide based compound, a titanium phosphate based compound, and zirconium phosphate based compound per 100 parts by mass of the at least one ethylene resin.

3. The solar cell encapsulant sheet of claim 1, wherein the material further comprises 0.001 parts by mass to 5 parts by mass of at least one compound (B) selected from the group consisting of a dialkyl peroxide and a compound having four or more (meth)acryloyl groups in its single molecule per 100 parts by mass of the at least one ethylene resin.

4. The solar cell encapsulant sheet of claim 1, wherein the at least one ethylene resin comprises an ethylene-α-olefin copolymer having a ratio (HL110) of the heat of fusion within a temperature range of from 20° C. to 110° C. to the total heat of fusion measured with a differential scanning calorimeter of 85% or more.

5. (canceled)

6. The solar cell encapsulant sheet of claim 1, wherein the material further comprises
0.001 parts by mass to 5 parts by mass of at least one compound (A) selected from the group consisting of silicon dioxide, zeolite, a bismuth oxide based compound, an antimony oxide based compound, a titanium phosphate based compound, and zirconium phosphate based compound per 100 parts by mass of the at least one ethylene resin,
0.001 parts by mass to 5 parts by mass of at least one compound (B) selected from the group consisting of a dialkyl peroxide and a compound having four or more (meth)acryloyl groups in its single molecule per 100 parts by mass of the at least one ethylene resin, and
the at least one ethylene resin comprises an ethylene-α-olefin copolymer having a ratio (HL110) of the heat of fusion within a temperature range of from 20° C. to 110° C. to the total heat of fusion measured with a differential scanning calorimeter of 85% or more.

7. A solar cell comprising a light receiving surface protector, a lower protector, a solar cell element, and at least one encapsulant sheet, wherein
said at least one encapsulant sheet formed of a material comprising at least one ethylene resin selected from the group consisting of an ethylene-α-olefin copolymer, an ethylene homopolymer, and an ethylene-unsaturated ester copolymer, wherein the volume resistivity value of the material measured at 23° C. is 1×10¹⁷ Ω·cm or more and the average luminous transmittance of the material within a wavelength range of from 400 nm to 1200 nm is 91% or more,
said at least one encapsulant sheet formed of a material comprising at least one ethylene resin selected from the group consisting of an ethylene-α-olefin copolymer, an ethylene homopolymer, and an ethylene-unsaturated ester copolymer, wherein the volume resistivity value of the material measured at 23° C. is 1×10¹⁷ Ω·cm or more and the average luminous transmittance of the material within a wavelength range of from 400 nm to 1200 nm is 91% or more, and 0.001 parts by mass to 5 parts by mass of at least one compound (A) selected from the group consisting of silicon dioxide, zeolite, a bismuth oxide based compound, an antimony oxide based compound, a titanium phosphate based compound, and zirconium phosphate based compound per 100 parts by mass of the at least one ethylene resin; or
said at least one encapsulant sheet formed of a material comprising at least one ethylene resin selected from the group consisting of an ethylene-α-olefin copolymer, an ethylene homopolymer, and an ethylene-unsaturated ester copolymer, wherein the volume resistivity value of the material measured at 23° C. is 1×10¹⁷ Ω·cm or more and the average luminous transmittance of the material within a wavelength range of from 400 nm to 1200 nm is 91% or more, 0.001 parts by mass to 5 parts by mass of at least one compound (A) selected from the group consisting of silicon dioxide, zeolite, a bismuth oxide based compound, an antimony oxide based compound, a titanium phosphate based compound, and zirconium phosphate based compound per 100 parts by mass of the at least one ethylene resin, and 0.001 parts by mass to 5 parts by mass of at least one compound (B) selected from the group consisting of a dialkyl peroxide and a compound having four or more (meth)acryloyl groups in its single molecule per 100 parts by mass of the at least one ethylene resin.

8. A solar cell comprising a light receiving surface protector, a lower protector, a solar cell element, and at least one encapsulant sheet according to claim 7, wherein said material said at least one ethylene resin comprises an ethylene-α-olefin copolymer having a ratio (HL110) of the heat of fusion within a temperature range of from 20° C. to 110° C. to the total heat of fusion measured with a differential scanning calorimeter of 85% or more.
